(19) United States
(12) Patent Application Publication
(10) Pub. No.: US 2025/0329606 A1
(43) Pub. Date: Oct. 23, 2025

(54) INTEGRATED CIRCUIT DEVICE INCLUDING A HIGH THERMAL CONDUCTIVITY ELECTRICALLY INSULATING STRUCTURE

(71) Applicant: Taiwan Semiconductor Manufacturing Company, Ltd., Hsinchu (TW)

(72) Inventors: Cheng-Chin Lee, Taipei City (TW); Hsin-Yen Huang, New Taipei City (TW); Shao-Kuan Lee, Kaohsiung City (TW); Ting-Ya Lo, Hsinchu (TW); Hsiao-Kang Chang, Hsinchu City (TW)

(21) Appl. No.: 19/254,228

(22) Filed: Jun. 30, 2025

Related U.S. Application Data
(63) Continuation of application No. 18/432,197, filed on Feb. 5, 2024.
(60) Provisional application No. 63/589,689, filed on Oct. 12, 2023.

(51) Int. Cl. H01L 23/373; H01L 23/00; H01L 23/367; H01L 23/498; H01L 25/065

(52) U.S. Cl. CPC H01L 23/3736; H01L 23/3675; H01L 23/49816; H01L 24/13; H01L 24/29; H01L 24/73; H01L 25/0657; H01L 2224/13005; H01L 2224/13025; H01L 2224/29009; H01L 2224/29022; H01L 2224/73153; H01L 2225/06517; H01L 2924/01029; H01L 2924/15311; H01L 2924/351

(57) ABSTRACT

Some embodiments relate to an integrated circuit (IC) device including a substrate, a plurality of electrically conductive structures disposed over the substrate and separated from each other, and at least one electrically insulating structure disposed over the substrate and directly contacting each of the plurality of electrically conductive structures. The at least one electrically insulating structure has a thermal conductivity greater than five watts per meter-Kelvin (W/m-K).

### REFERENCE TO RELATED APPLICATIONS

This Application is a Continuation of U.S. application Ser. No. 18/432,197, filed on Feb. 5, 2024, which claims the benefit of U.S. Provisional Application No. 63/589,689, filed on Oct. 12, 2023. The contents of the above-referenced Patent Applications are hereby incorporated by reference in their entirety.

### BACKGROUND

Advances in integrated circuit (IC) design extend beyond reductions in circuit geometries to multi-level chip/wafer designs, packaging innovations, and the like. Such advances may address a previously recognized need, but in some cases, may also create a separate issue. One such issue is the generation of excess heat that may negatively impact the performance or physical integrity of the IC.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a schematic cross-sectional view of some embodiments of an IC device employing a thermal collection network that includes a highly thermally conductive electrically insulating structure, according to the present disclosure.

FIGS. 2A-2C, FIGS. 3A-3C, FIGS. 4A-4C, and FIGS. 5A-5C illustrate plan views and cross-sectional views of some embodiments of a highly thermally conductive electrically insulating structure in various configurations relative to a plurality of electrically conductive structures, according to the present disclosure.

FIGS. 6A-6C illustrate a plan view and cross-sectional views of some embodiments of an IC device employing a plurality of highly thermally conductive electrically insulating structures coupled to a plurality of electrically conductive structures, according to the present disclosure.

FIGS. 7A-7C illustrate cross-sectional views of some embodiments of an IC device in which a thickness of at least one highly thermally conductive electrically insulating structure varies within a dielectric layer, according to the present disclosure.

FIGS. 8A-8C illustrate cross-sectional views of some embodiments of an IC device in which a thickness of at least one highly thermally conductive electrically insulating structure varies across one or more dielectric layers, according to the present disclosure.

FIGS. 9A and 9B illustrate cross-sectional views of some embodiments of an IC device in which a functionality of the one or more of the plurality of electrically conductive structures varies, according to the present disclosure.

FIGS. 10A-10C illustrate a plan view and cross-sectional views of some embodiments of an IC device employing a plurality of discrete highly thermally conductive electrically insulating structures connected to the plurality of electrically conductive structures, according to the present disclosure.

FIGS. 11A-11C illustrate a plan view and cross-sectional views of some embodiments of an IC device employing a single highly thermally conductive electrically insulating structure connected to the plurality of electrically conductive structures, according to the present disclosure.

FIGS. 12A through 12L illustrate cross-sectional views of some embodiments of an IC device employing a plurality of highly thermally conductive electrically insulating structures, as shown in FIGS. 10A-10C, at various stages of manufacture, according to the present disclosure.

FIGS. 13A and 13B illustrate cross-sectional views of some embodiments employing two-step etching of a highly thermally conductive electrically insulating structure preceding deposition of a plurality of electrically conductive structures, according to the present disclosure.

FIGS. 14A and 14B illustrate cross-sectional views of some embodiments employing one-step etching of a highly thermally conductive electrically insulating structure preceding deposition of a plurality of electrically conductive structures, according to the present disclosure.

FIG. 15 illustrates a methodology of forming an IC device employing at least one highly thermally conductive electrically insulating structure to be coupled with a plurality of electrically conductive structures, in accordance with some embodiments of the present disclosure.

FIG. 16 illustrates a methodology of forming an IC device employing a plurality of highly thermally conductive electrically insulating structures to be coupled with a plurality of electrically conductive structures, in accordance with some embodiments of the present disclosure.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A somewhat recent advance in IC design is the positioning of electrically conductive structures for signals and power over opposing sides of a semiconductor substrate. More specifically, by implementing the power conductive structures as buried power rails in the substrate and/or as backside power rails near a backside surface of the substrate, additional useful volume may be available inside the IC device for both types of conductive structures. However, a potential undesirable side effect of placing the electrically conductive structures and their associated dielectric layers over both sides of the substrate is the retention of heat generated by the IC components (e.g., transistors and so on) incorporated in and/or adjacent to the substrate, due primarily to the low thermal conductivity sometimes associated with the dielectric materials used in the dielectric layers. Further, in some cases, the dielectric layers that carry the power conductive structures over the backside of the substrate are sometimes thicker than what may normally be employed over a frontside of the substrate, thus potentially increasing the retention of thermal energy in and near the substrate.

To address these issues, the present disclosure provides some embodiments of an IC device that employs at least one electrically insulating structure that has a thermal conductivity greater than that of typical dielectric materials, such as silicon dioxide (SiO₂), that are often used within IC devices. In some embodiments, the at least one electrically insulating structure may be diamond, although other dielectric or electrically insulating materials may be employed in other implementations.

In some embodiments, an IC device may include a substrate, a plurality of electrically conductive structures disposed over the substrate and separated from each other, and at least one electrically insulating structure disposed over the substrate and directly contacting each of the plurality of electrically conductive structures. In some embodiments, the at least one electrically insulating structure may have a thermal conductivity greater than 1 watt per meter-Kelvin (W/m-K), while in other embodiments, the at least one electrically insulating structure may have a thermal conductivity significantly greater than 1 W/m-K (e.g., 2, 5, 10, 20, 30 or more W/m-K). In some embodiments, such an electrically insulating structure may be described herein as a highly thermally conductive electrically insulating structure, or a high thermal conductivity electrically insulating structure. Accordingly, in some embodiments, a low thermal conductivity electrically insulating structure may be one with a thermal conductivity of approximately 1 W/m-K or less.

Thus, in some embodiments, the at least one electrically insulating structure may serve as a thermal energy conduit to carry heat from some of the plurality of electrically conductive structures to others of the plurality of electrically conductive structures that may be coupled to vias that carry that heat to an external area of the IC device, such as a heat sink, solder connection, or another interface with the external environment. The electrically insulating structures, as described in greater detail below, may thus lead to better operational characteristics and a longer expected lifetime for an IC device that employs such electrically insulating structures.

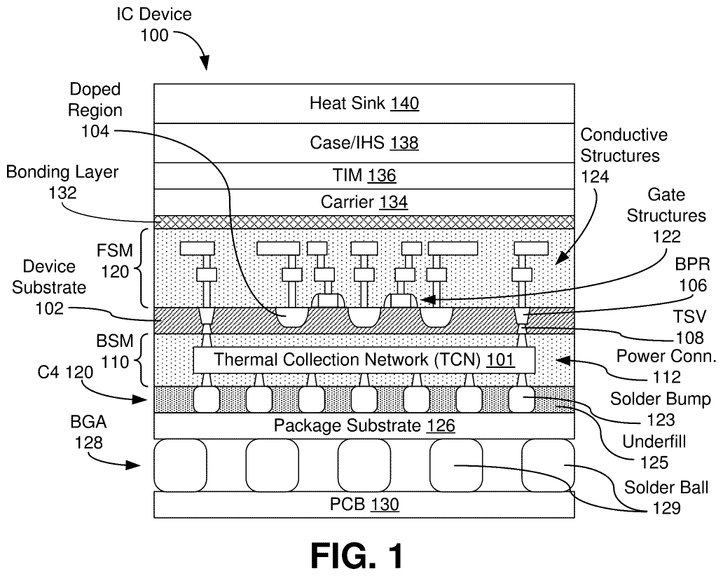

FIG. 1 illustrates a schematic cross-sectional view of some embodiments of an IC device 100 employing a thermal collection network (TCN) 101 that includes a highly thermally conductive electrically insulating structure, according to the present disclosure. IC device 100 employs buried power rails (BPRs) 106 within a device substrate 102, resulting in the use of a backside metal (BSM) area 110 (e.g., carrying power connections 112) in additional to a frontside metal (FSM) area 120 (e.g., carrying electrically conductive structures 124). In addition, device substrate 102 includes through-silicon vias (TSVs) 108, such as nano-TSVs (nTSVs), coupling BPRs 106 to power connections 112 in BSM 110.

In such a configuration, conductive structures 124 of FSM 120 may carry electrical signals associated with transistors and other components implemented by way of doped (e.g., n-doped or p-doped) regions 104 in device substrate 102 and associated gate structures 122 in FSM 120. The operation of these components may result in significant heat generation at least in device substrate 102 and lower portions of FSM 120, as well as in BPRs 106 and TSVs 108 in device substrate 102 and power connections 112 of BSM 110. As indicated above, dissipation of the resulting heat may be difficult due to the use of low thermal conductivity dielectric materials carrying conductive structures 124 and power connections 112 in FSM 120 and BSM 110. In addition, in such configurations, device substrate 102 may be thinned to facilitate the use of BPRs 106 and TSVs 108 to carry power between FSM 120 and BSM 110. BSM 110 may also carry various signal connections from FSM 120 and received via device substrate 102 and conductive structures 124.

Consequently, in embodiments described in greater detail below, a thermal collection network (TCN) 101 that includes a plurality of electrically conductive structures and at least one high thermal conductivity electrically insulating structure may be disposed within BSM 110 to facilitate enhanced distribution of thermal energy through BSM 110 away from device substrate 102.

Continuing with FIG. 1, various signal connections and power connections 112 may be made between IC device 100 and a printed circuit board 130 on which IC device 100 is mounted by multiple connection layers. More specifically, signal connections and power connections 112 may be made with solders bumps 123 that couple BSM 110 with a package substrate 126. Solder bumps 123, which may be deposited on chip pads provided on BSM 110 and/or package substrate 126, may provide what may be referred to as a controlled-collapse chip connection (C4). In some embodiments, to enhance mechanical stability, an underfill 125 of a non-conductive material may fill the void among solder bumps 123, BSM 110, and package substrate 126. In turn, package substrate 126 may include conductive elements that connect solder bumps 123 to solder balls 129 (e.g., forming a ball grid array (BGA) 128) that may mechanically and electrically connect package substrate 126 to printed circuit board 130.

At the opposing side of device substrate 102, FSM 120 may be coupled to a carrier 134 for IC device 100 via a bonding layer 132. Thereafter, a case/integrated heat spreader (IHS) 138 may be mechanically coupled to carrier 134 via a thermal interface material (TIM) 136.

Finally, a heat sink 140 may be attached to case/IHS 138 (e.g., by way of a thermal adhesive not shown in FIG. 1) to facilitate removal of heat from a top surface of FSM 120.

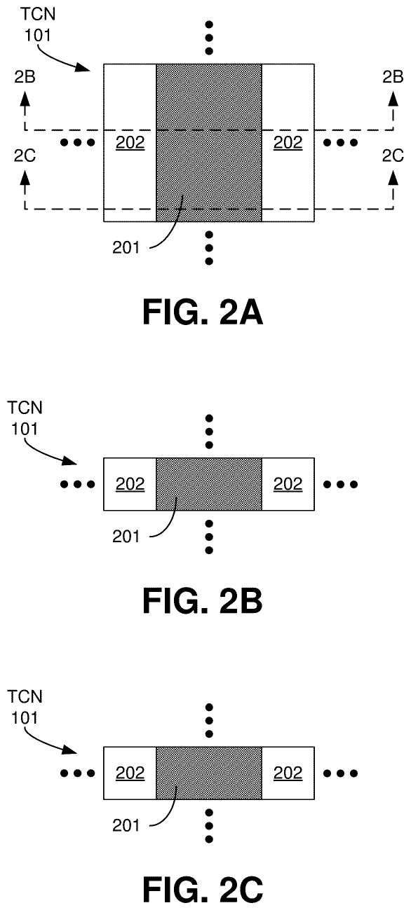

FIGS. 2A-2C, FIGS. 3A-3C, FIGS. 4A-4C, and FIGS. 5A-5C illustrate plan views and cross-sectional views of some embodiments of a highly thermally conductive electrically insulating structure 201 in various configurations relative to a plurality of electrically conductive structures 202, according to the present disclosure. These views may correspond to some portion of TCN 101 of FIG. 1, although TCN 101 and the various embodiments described below may be employed in various IC configurations other than that depicted for IC device 100 in FIG. 1.

Each of FIGS. 2A-2C, FIGS. 3A-3C, FIGS. 4A-4C, and FIGS. 5A-5C illustrate basic physical relationships between electrically insulating structure 201 and electrically conductive structures 202 that facilitate distribution of thermal energy among electrically conductive structures 202 such that any of the electrically conductive structures 202 that do not directly connect with vias or other electrically conductive structures that may carry heat may instead deliver that heat via electrically insulating structure 201 to another electrically conductive structure 202 that may distribute that heat elsewhere.

For example, FIGS. 2A, 2B, and 2C illustrate a plan view, a first cross-sectional view, and a second cross-sectional view, respectively, of some embodiments of a high thermal conductivity dielectric structure 201 bridging a space between two conductive structures 202 aligned in parallel. In these embodiments, electrically insulating structure 201 may be disposed along a significant length of electrically conductive structures 202 to the exclusion of other dielectric materials. More specifically, at each cross-section along electrically conductive structures 202, electrically insulating structure 201 may fill at least the majority of space between electrically conductive structures 202 (e.g., contacting electrically conductive structures 202 at surfaces that face the opposing electrically conductive structure 202).

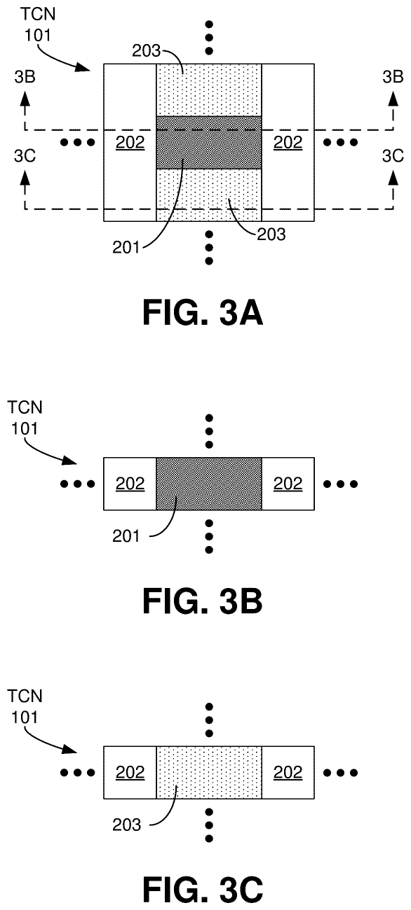

FIGS. 3A, 3B, and 3C illustrate a plan view, a first cross-sectional view, and a second cross-sectional view, respectively, of some embodiments of a high thermal conductivity electrically insulating structure 201 bridging a portion of the space between two conductive structures 202 aligned in parallel. In these embodiments, electrically insulating structure 201 may be disposed along a relatively short length of electrically conductive structures 202, with a remainder of the space between electrically conductive structures 202 being occupied by a dielectric material 203 (e.g., SiO₂ or another dielectric material) having a lower thermal conductivity (e.g., 1 W/m-K) than electrically insulating structure 201. Consequently, at some cross-sections along electrically conductive structures 202 (e.g., as shown in FIG. 3B), electrically insulating structure 201 may fill the space between electrically conductive structures 202 (e.g., contacting electrically conductive structures 202 at surfaces that face the opposing electrically conductive structure 202), while at other cross-sections (e.g., as illustrated in FIG. 3C), lower thermal conductivity dielectric structure 203 may fill the corresponding space between electrically conductive structures 202. In other embodiments, more than one high thermal conductivity electrically insulating structure 201 may be distributed along electrically conductive structures 202 to make contact there between, interspersed with low thermal conductivity structures 203 there between.

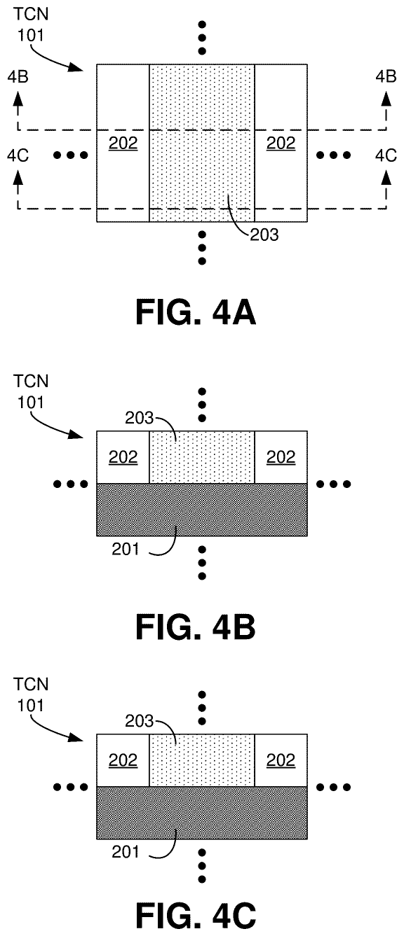

FIGS. 4A, 4B, and 4C illustrate a plan view, a first cross-sectional view, and a second cross-sectional view, respectively, of some embodiments of a high thermal conductivity electrically insulating structure 201 that couples corresponding parallel surfaces (e.g., downward-facing surfaces, as shown in FIGS. 4B and 4C, or upward-facing surfaces) of electrically conductive structures 202 (e.g., such that electrically insulating structure 201 is disposed in an adjacent layer to that of conductive structures 202). In some embodiments, low thermal conductivity dielectric structure 203 may fill the space between electrically conductive structures 202 in a manner similar to that of electrically insulating structure 201 of FIGS. 2A-2C. Moreover, in some embodiments, both high thermal conductivity electrically insulating structures 201 and low thermal conductivity dielectric structures 203 may extend along a significant length of electrically conductive structures 202, as shown at multiple cross-sections of FIG. 4A, such as at FIGS. 4B and 4C.

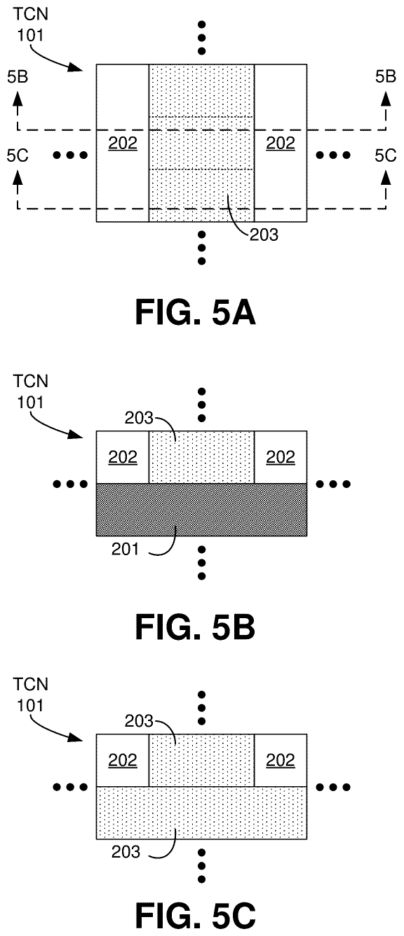

FIGS. 5A, 5B, and 5C illustrate a plan view, a first cross-sectional view, and a second cross-sectional view, respectively, of some embodiments of a high thermal conductivity electrically insulating structure 201 that couples corresponding parallel surfaces (e.g., downward-facing surfaces, as shown in FIGS. 5B and 5C, or upward-facing surfaces) of electrically conductive structures 202 (e.g., such that electrically insulating structure 201 is disposed in an adjacent layer to that of electrically conductive structures 202). In some embodiments, low thermal conductivity dielectric structure 203 may fill the space between electrically conductive structures 202, as well as spaces adjacent high thermal conductivity electrically insulating structure 201, as shown in FIG. 5C, for example. Consequently, in some embodiments, both high thermal conductivity electrically insulating structures 201 and low thermal conductivity dielectric structures 203, in alternating fashion, may extend along a significant length of electrically conductive structures 202 under (or over) conductive structures 202, while low thermal conductivity dielectric structure 203 also substantially fills the region between electrically conductive structures 202 substantially along the entire length of electrically conductive structures 202.

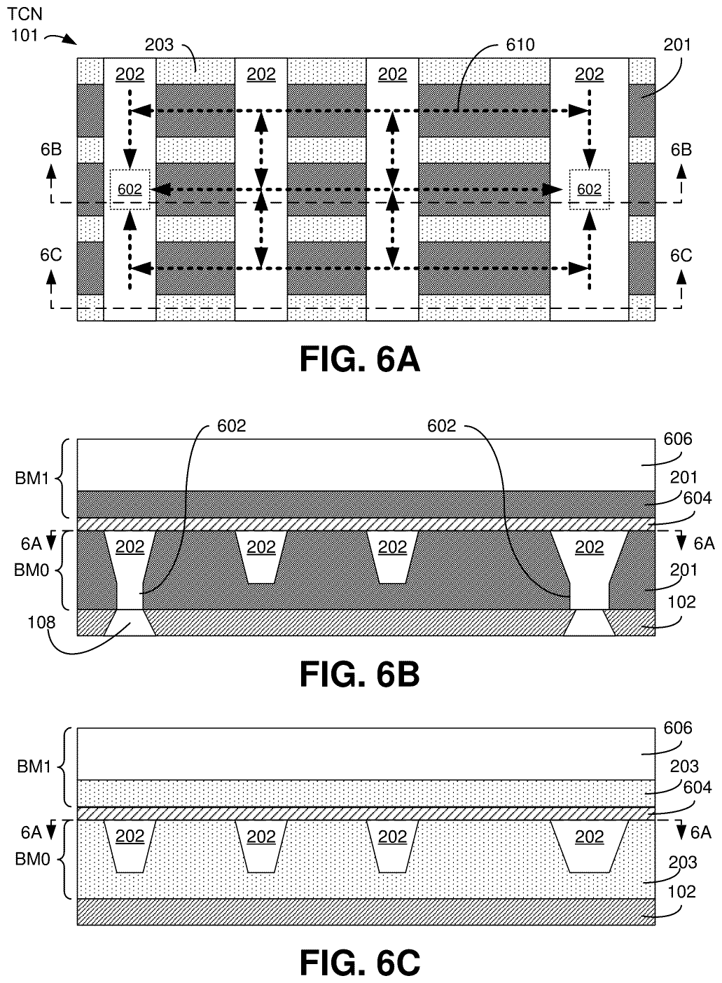

FIGS. 6A-6C illustrate a plan view, a first cross-sectional view, and a second cross-sectional view, respectively, of some embodiments of an IC device employing a plurality of high thermal conductivity electrically insulating structures 201 coupled to a plurality of electrically conductive structures 202, according to the present disclosure. In some embodiments, as shown in FIGS. 6B and 6C, as well as others described below, electrically conductive structures 202, electrically insulating structures 201, and dielectric structures 203 are employed in a TCN 101 disposed in a BSM 110 having at least two backside metal layers: a first backside metal layer BM0 and a second backside metal layer BM1. Other configurations of an IC device 100 in which TCN 101 may be employed are also possible.

In FIGS. 6A-6C, alternating regions of high thermal conductivity electrically insulating structures 201 and low thermal conductivity dielectric structures 203 are disposed over substrate 102 (e.g., a semiconductor substrate, such as silicon). In some embodiments, low thermal conductivity dielectric structures 203 may include one or more dielectric materials, including, but not limited to, silicon oxide (SiOₓ) (e.g., silicon oxide (SiO₂)), carbon-doped silicon dioxide, silicon oxynitride, borosilicate glass (BSG), phosphorus silicate glass (PSG), borophosphosilicate (BPSG), fluorosilicate glass (FSG), un-doped silicate glass (USG), a porous dielectric material, or the like. Further, in some embodiments, high thermal conductivity electrically insulating structures 201 may include one or more materials with a higher thermal conductivity than the thermal conductivity of low thermal conductivity dielectric structures 203. For example, presuming low thermal conductivity dielectric structures 203 possess a thermal conductivity of 1 W/m-K, high thermal conductivity electrically insulating structures 201 may have a thermal conductivity greater than 1 W/m-K in some embodiments. For example, in some embodiments, high thermal conductivity electrically insulating structures 201 may have a thermal conductivity greater than or equal to 2 W/m-K. In other embodiments, high thermal conductivity electrically insulating structures 201 may have a thermal conductivity greater than or equal to 5 W/m-K. In other embodiments, high thermal conductivity electrically insulating structures 201 may have a thermal conductivity greater than or equal to 10 W/m-K. In some other embodiments, high thermal conductivity electrically insulating structures 201 may have a thermal conductivity greater than or equal to 20 W/m-K. In yet other embodiments, high thermal conductivity electrically insulating structures 201 may have a thermal conductivity greater than or equal to 30 W/m-K. Examples of insulating or dielectric materials that may serve as high thermal conductivity electrically insulating structures 201 may include, but are limited to, diamond, aluminum nitride (AlN), silicon carbide (SiC), silicon nitride (SiN), boron nitride (BN), or beryllium oxide (BeO).

As depicted in FIGS. 6A-6C, a plurality of electrically conductive structures 202 are disposed within both high thermal conductivity electrically insulating structures 201 and low thermal conductivity dielectric structures 203. More specifically, electrically conductive structures 202 may extend laterally along a first longitudinal axis (e.g., upward and downward, as shown in FIG. 6A) while both high thermal conductivity electrically insulating structures 201 and low thermal conductivity dielectric structures 203 extend laterally along a second longitudinal axis perpendicular to the first longitudinal axis (e.g., leftward and rightward in FIG. 6A). In some embodiments, electrically conductive structures 202 may include a metal (e.g., copper (Cu)), a metal alloy, or another conductive material. In some embodiments, conductive structures 202 may also possess a high thermal conductivity (e.g., greater than low thermal conductivity dielectric structures 203).

In some embodiments, as illustrated in FIGS. 6B and 6C, a first backside metal layer BM0 may be disposed over substrate 102 that includes both high thermal conductivity electrically insulating structures 201 and low thermal conductivity dielectric structures 203, along with electrically conductive structures 202. In addition, an etch stop layer (ESL) 604 may be disposed over first backside metal layer BM0. In some embodiments, ESL 604 may include silicon nitride (SiN), silicon carbon nitride (SiCN), or another metal-based oxide and/or nitride material. Also, in some embodiments, ESL 604 may be formed using physical vapor deposition (PVD), chemical vapor deposition (CVD), atomic layer deposition (ALD), or the like. Further, ESL 604, in some embodiments, may range from approximately 30 angstroms to approximately 200 angstroms in thickness, based on the material employed for ESL 604.

Further, in some embodiments, a second backside metal layer BM1 may be disposed over first backside metal layer BM0 and ESL 604 and may include at least one electrically conductive structure 606 over one or both of high thermal conductivity electrically insulating structures 201 and low thermal conductivity dielectric structures 203.

As also shown in FIGS. 6B and 6C, one or more electrically conductive structures 202 may extend to an upper surface of substrate 102 (e.g., by way of a via 602 or other electrically conductive structure). Further, in some embodiments, one or more TSVs (e.g., nTSVs) 108 may be disposed in substrate 102 and connected to corresponding electrically conductive structures 202, thus providing an electrical and thermal path from an electrically conductive structure 202 to TSV 108. Accordingly, in some embodiments, high thermal conductivity electrically insulating structures 201 may provide effective thermal paths coupling electrically conductive structures 202 together so that those electrically conductive structures 202 not electrically connected to a TSV 108 may pass thermal energy via one or more high thermal conductivity electrically insulating structures 201 to an electrically conductive structure 202 that is electrically connected to a TSV 108. FIG. 6A depicts potential thermal paths 610 by way of dashed arrows.

Consequently, in some embodiments, the use of one or more high thermal conductivity electrically insulating structures 201 provides additional thermal pathways to facilitate heat dissipation. Moreover, such thermal pathways use the same electrically conductive vias 602 that also would be employed for distribution of electrical power and/or signal flows; consequently, no IC area penalty is imposed as a result of the use of high thermal conductivity electrically insulating structures 201. Additionally, in some embodiments, the use of one or more high thermal conductivity electrically insulating structures 201 in less than all of the area of substrate 102 in a plan view (e.g., as shown in FIG. 6A) may result in fewer process integration difficulties than may otherwise exist when incorporating high thermal conductivity electrically insulating structures 201.

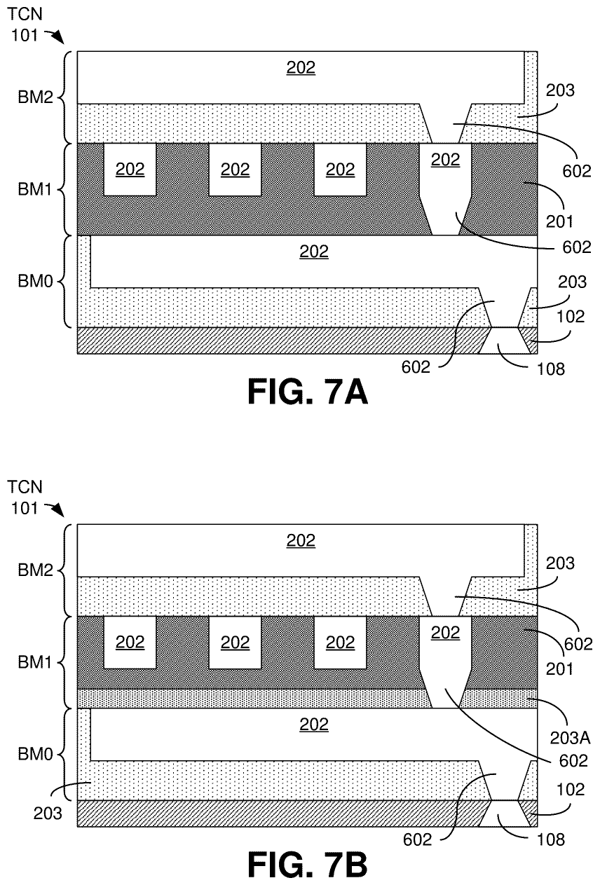

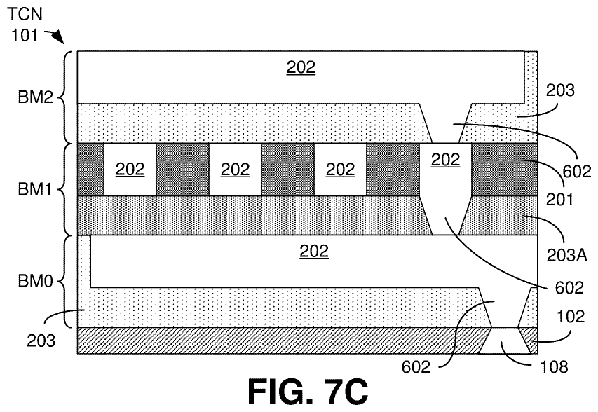

FIGS. 7A-7C, FIGS. 8A-8C, FIGS. 9A-9C, FIGS. 10A-10C, and FIGS. 11A-11C illustrate various plan views and cross-sectional views of some embodiments of an IC device employing another backside metal structure in which at least one highly thermally conductive electrically insulating structure 201 is utilized. In each of these embodiments, a first backside metal layer BM0, a second backside metal layer BM1, and a third backside metal layer BM3 are disposed, in order, over a substrate 102. One or more electrically conductive structures 202 and associated vias 602 may be disposed in each of first backside metal layer BM0 and third backside metal layer BM2. Further, first backside metal layer BM0 may include a low thermal conductivity dielectric structure 203, while third backside metal layer BM2 may include low thermal conductivity dielectric structure 203 or high thermal conductivity electrically insulating structure 201.

Further, in some embodiments, a plurality of electrically conductive structures 202 are included in second backside metal layer BM1, with at least one of electrically conductive structures 202 being connected via a corresponding via to an electrically conductive structure 202 of first backside metal layer BM0 and/or third backside metal layer BM2. In some embodiments, electrically conductive structures 202 of second backside metal layer BM1 may each have a longitudinal axis aligned laterally parallel to the longitudinal axis of the other electrically conductive structures 202. Also, in some embodiments, the plurality of electrically conductive structures 202 in any of backside metal layers BM0, BM1, and/or BM2 may have a width of 36 nanometers (nm) or more and a spacing there between (e.g., a pitch) of 36 nm or more.

While the figures described below may depict only a small portion of TCN 101, in some embodiments, an area in a plan view of TCN 101 may extend laterally across substantially all of substrate 102 with IC device 100, or may be limited to a smaller area of substrate 102 to address a portion of IC device 100 that is associated with a heat dissipation issue.

FIGS. 7A-7C illustrate cross-sectional views of some embodiments of an IC device in which a thickness of at least one highly thermally conductive electrically insulating structure varies within a dielectric layer, according to the present disclosure. For example, in FIG. 7A, at least one high thermal conductivity electrically insulating layer 201 extends vertically through an entirety of second backside metal layer BM1. In FIG. 7B, at least one high thermal conductivity electrically insulating layer 201 extends downward from an upper surface of second backside metal layer BM1 to an intermediate depth between at least some of electrically conductive structures 202 and an upper surface of first backside metal layer BM0. In some embodiments, another low thermal conductivity dielectric layer 203A may be disposed to fill the remaining depth of second backside metal layer BM1 below high thermal conductivity electrically insulating layer 201. In FIG. 7C, at least one high thermal conductivity electrically insulating layer 201 extends downward from an upper surface of second backside metal layer BM1 to a lower surface of at least some of electrically conductive structures 202, while another low thermal conductivity dielectric layer 203A may be disposed to fill the remaining depth of second backside metal layer BM1 below high thermal conductivity electrically insulating layer 201 and at least some conductive structures 202. In some embodiments, the low thermal conductivity dielectric layer 203A may include the same or different dielectric materials as low thermal conductivity dielectric structure 203 and, like low thermal conductivity dielectric structure 203, may have a thermal conductivity that is less than that of high thermal conductivity electrically insulating structure 201.

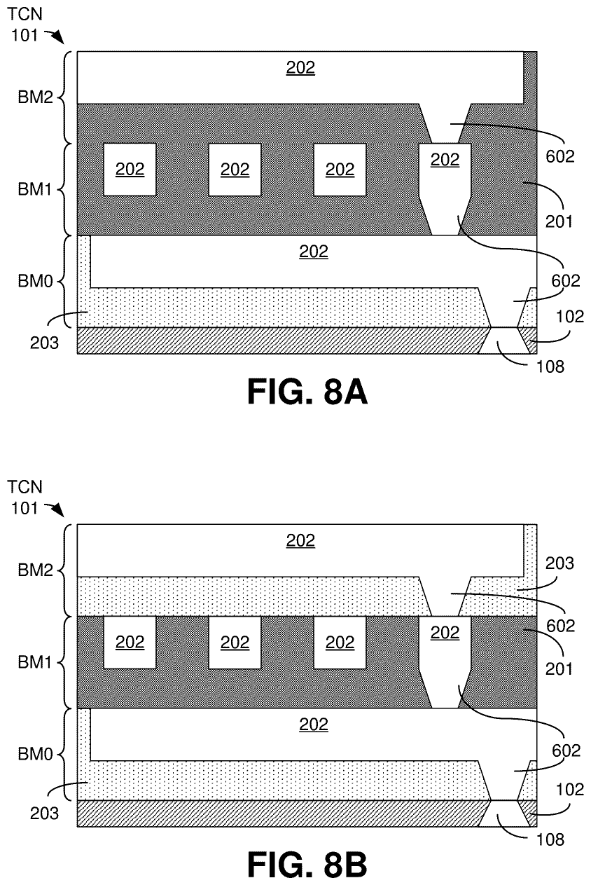

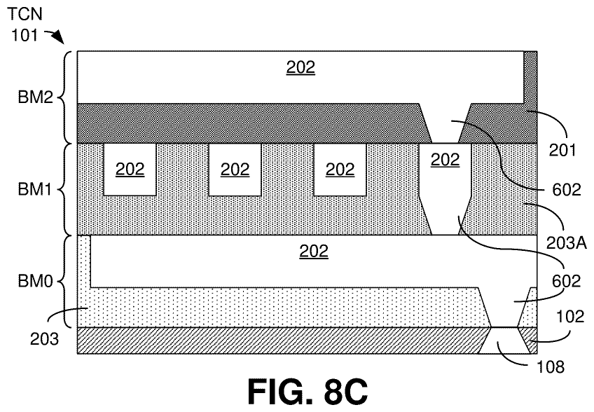

FIGS. 8A-8C illustrate cross-sectional views of some embodiments of an IC device in which a thickness of at least one highly thermally conductive electrically insulating structure varies across one or more dielectric layers, according to the present disclosure. For example, in FIG. 8A, one or more high thermal conductivity electrically insulating structures 201 fill substantially all portions of second backside metal layer BM1 and third backside metal layer BM2 not occupied by electrically conductive structures 202 and corresponding vias 602. In FIG. 8B, one or more high thermal conductivity electrically insulating structures 201 fill substantially all portions of second backside metal layer BM1 not occupied by conductive structures 202 and corresponding vias 602, while low thermal conductivity dielectric structure 203 fills substantially all portions of third backside metal layer BM2 not occupied by electrically conductive structures 202 and corresponding vias 602. In FIG. 8C, one or more high thermal conductivity electrically insulating structures 201 fill substantially all portions of third backside metal layer BM2 not occupied by electrically conductive structures 202 and corresponding vias 602, while low thermal conductivity dielectric structure 203 or low thermal conductivity dielectric layer 203A fills substantially all portions of second backside metal layer BM1 not occupied by electrically conductive structures 202 and corresponding vias 602.

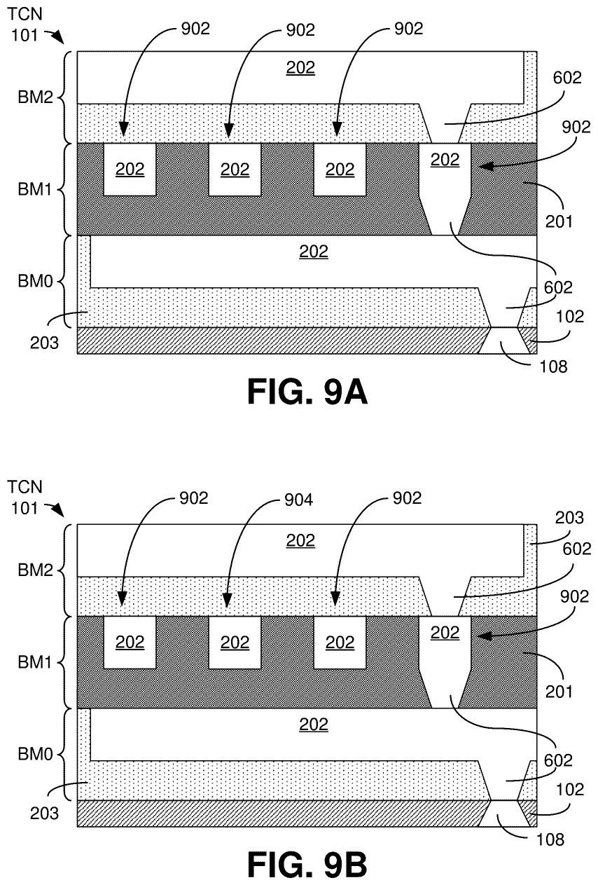

FIGS. 9A and 9B illustrate cross-sectional views of some embodiments of an IC device in which a functionality of the one or more of the plurality of electrically conductive structures varies, according to the present disclosure. For example, in FIG. 9A, of those electrically conductive structures 202 of second backside metal layer BM1 not connected to a corresponding via 602, each may serve as a signal or power connection 902. In FIG. 9B, of those conductive structures 202 of second backside metal layer BM1 not connected to a corresponding via 602, some may serve as a signal or power connection 902 while one or more others may serve as a “dummy” connection 904. In some embodiments, dummy connection 904 may not be connected to a signal or power level but may instead primarily serve as a thermal pathway to distribute thermal energy, as described above. In other embodiments, dummy connection 904 may be connected to a ground connection (e.g., to reduce noise coupling between signals) in addition to serving as a thermal conductor.

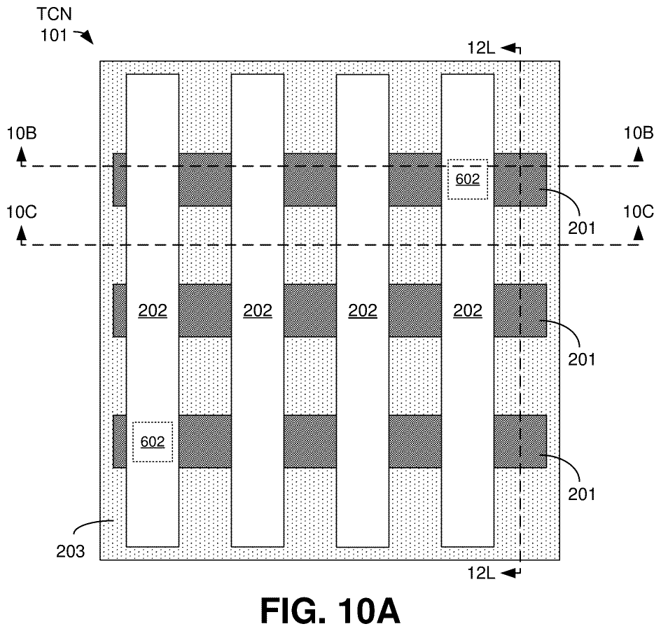

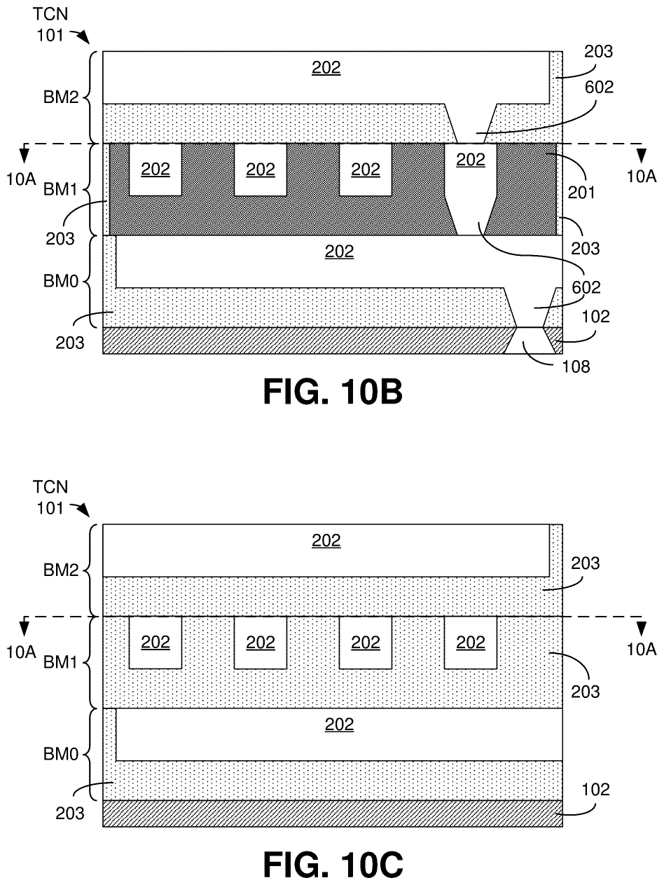

FIGS. 10A-10C illustrate a plan view, a first cross-sectional view, and a second cross-sectional view, respectively, of some embodiments of an IC device employing a plurality of discrete highly thermally conductive electrically insulating structures connected to the plurality of electrically conductive structures, according to the present disclosure. As shown in FIGS. 10A-10C, a plurality of high thermal conductivity electrically insulating structures 201 extending laterally (e.g., leftward and rightward in FIG. 10A) may couple with a plurality of electrically conductive structures 202 within second backside metal layer BM1, in a manner similar to that discussed above in conjunction with first backside metal layer BM0 of FIGS. 6A-6C. While high thermal conductivity electrically insulating structures 201 are shown to fill second backside metal layer BM1 in the manner depicted in FIG. 7A, other configurations for high thermal conductivity electrically insulating structures 201 shown in FIGS. 7B, 7C, and 8A-8C may also be employed as embodiments in connection with FIGS. 10A-10C.

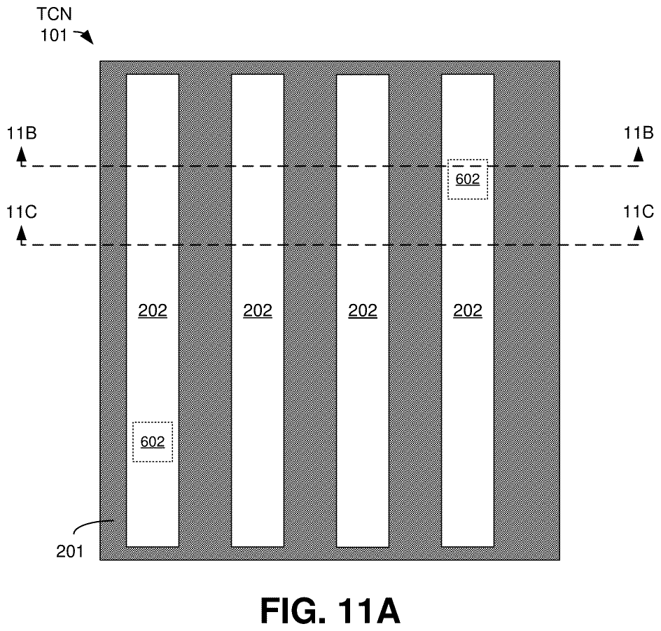

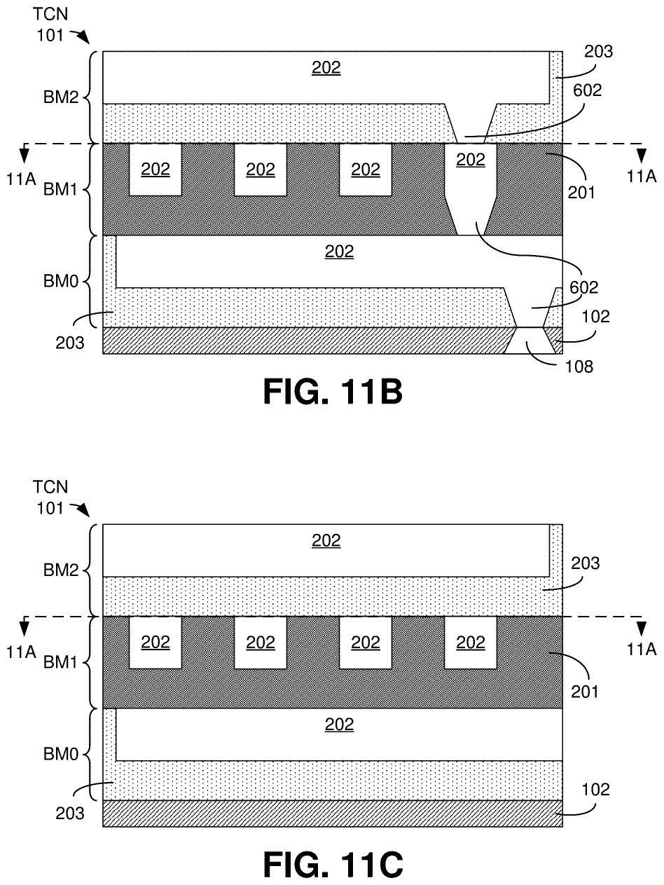

FIGS. 11A-11C illustrate a plan view, a first cross-sectional view, and a second cross-sectional view, respectively, of some embodiments of an IC device employing a single highly thermally conductive electrically insulating structure connected to the plurality of electrically conductive structures, according to the present disclosure. As shown in FIGS. 11A-11C, a single contiguous high thermal conductivity electrically insulating structure 201 connects with a plurality of electrically conductive structures 202 within second backside metal layer BM1. While high thermal conductivity electrically insulating structure 201 is shown to fill second backside metal layer BM1, in the manner depicted in FIG. 7A, other configurations for high thermal conductivity electrically insulating structure 201 shown in FIGS. 7B, 7C, and 8A-8C may also be employed as embodiments in connection with FIGS. 11A-11C.

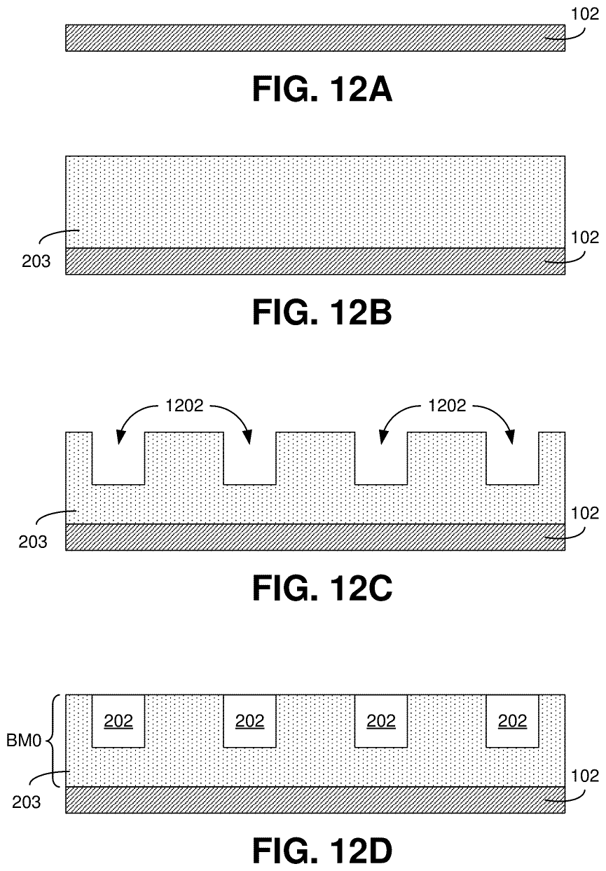

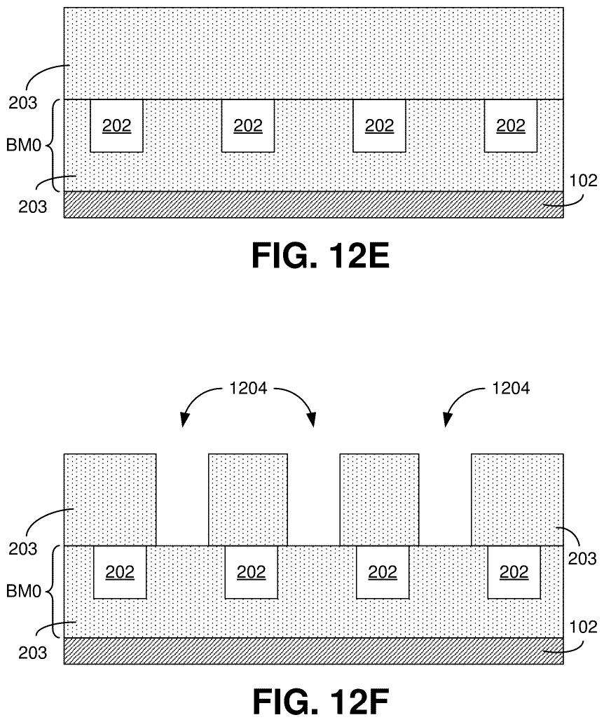

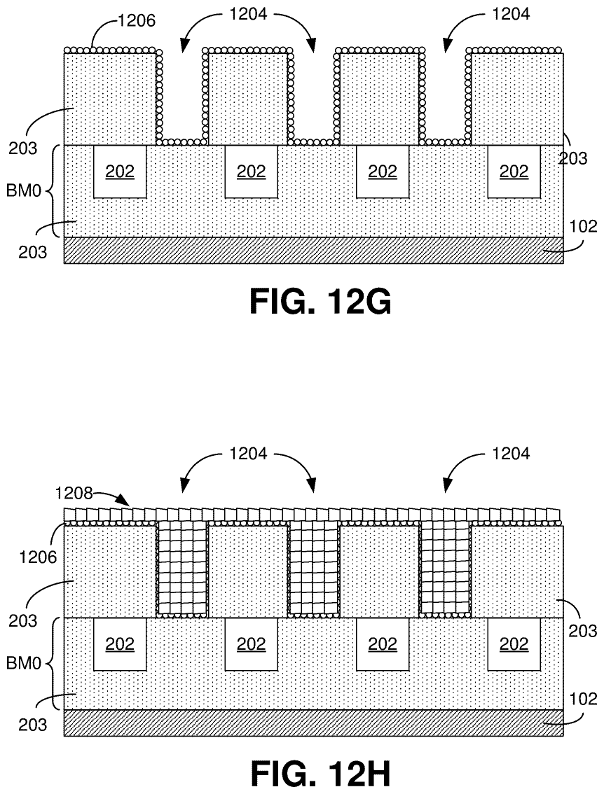

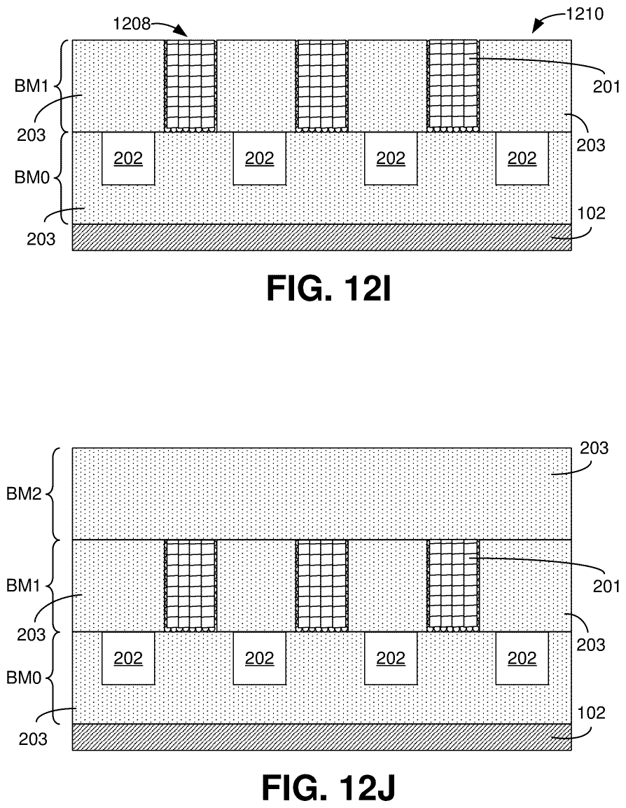

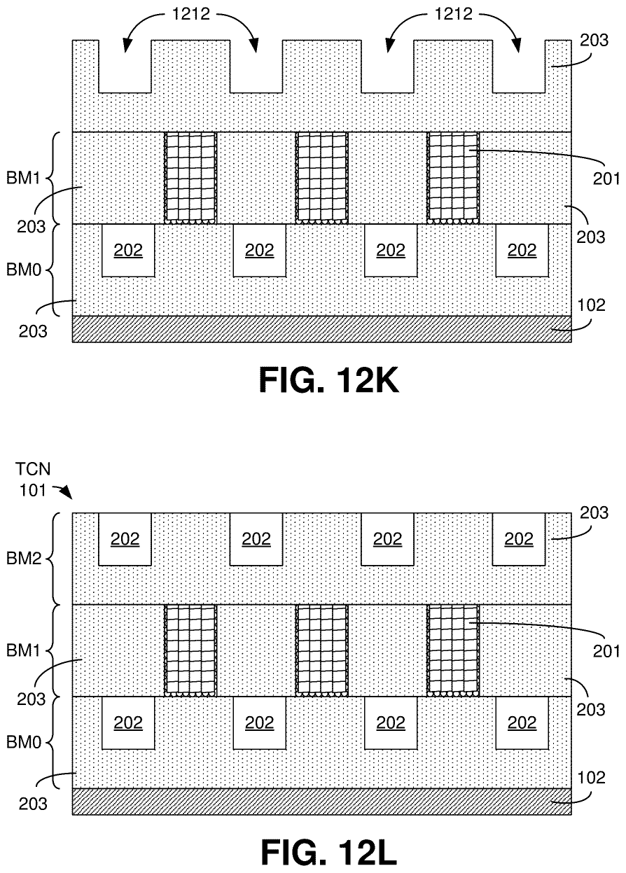

FIGS. 12A through 12L illustrate cross-sectional views of some embodiments of an IC device employing a plurality of highly thermally conductive electrically insulating structures (e.g., as shown in FIGS. 10A-10C) at various stages of manufacture, according to the present disclosure. Although FIGS. 12A through 12L are described as a series of acts, it will be appreciated that these acts are not limiting in that the order of the acts within each series can be altered in other embodiments, and the methods disclosed are also applicable to other structures. In other embodiments, some acts that are illustrated and/or described may be omitted in whole or in part. Also, in some embodiments, the highly thermally conductive electrically insulating structures may include diamond, although other materials having a high thermal conductivity (e.g., greater than 1, 2, 5, 10, 20, 30, or greater W/m-K, depending on the embodiment) may be included in other examples. For instance, some diamond may have dielectric properties including a low dielectric constant of 5.7 and a high dielectric strength of 1,000,000 V/cm.

For example, FIG. 12A illustrates a substrate 102 (e.g., a semiconductor substrate, such as a silicon substrate). In some embodiments, substrate 102 serves as a substrate for a backside metal (BSM) area, such as BSM 110 of FIG. 1, the fabrication of which is described more fully below in connection with FIGS. 12B-12L. Further, in some embodiments, substrate 102 may serve as a substrate for a frontside metal (FSM) area, such as FSM 120 of FIG. 1. The presence of FSM 120 or other portions of IC device 100 of FIG. 1 is not explicitly depicted in FIGS. 12A-12L, however, to simplify the following discussion. Additionally, in some embodiments, substrate 102 may be a substrate that has been thinned to facilitate the forming of FSM 120 and BSM 110 on supposing surfaces of substrate 102. Also, in some embodiments, substrate 102 may include doped regions (e.g., doped regions 104 of FIG. 1), but such regions are not depicted in FIGS. 12A-12L to simplify the following discussion.

FIG. 12B illustrates the forming (e.g., deposition) of a low thermal conductivity dielectric layer 203 over substrate 102. As mentioned above, in some embodiments, low thermal conductivity layer 203 may include at least one dielectric material, including, but not limited to, silicon oxide (SiOₓ) (e.g., silicon oxide (SiO₂)), carbon-doped silicon dioxide, silicon oxynitride, borosilicate glass (BSG), phosphorus silicate glass (PSG), borophosphosilicate (BPSG), fluorosilicate glass (FSG), un-doped silicate glass (USG), a porous dielectric material, or the like.

FIG. 12C illustrates the forming (e.g., etching) of a plurality of trenches 1202 at an upper surface of low thermal conductivity layer 203. In some embodiments, trenches 1202 may extend partway (e.g., approximately halfway) into low thermal conductivity dielectric layer 203.

FIG. 12D illustrates the forming (e.g., deposition) of at least one electrically conductive structure 202 to substantially complete a first backside metal layer BM0. In some embodiments, at least one electrically conductive structure 202 may serve to provide power and/or signal connections between substrate 102 and other electrically conductive structures disposed over first backside metal layer BM0. In some embodiments, the forming of at least one electrically conductive structure 202 may be followed by a planarizing operation, such as chemical-mechanical planarization (CMP). In some embodiments, electrically conductive structures 202 may include a metal (e.g., copper (Cu)), a metal alloy, or another conductive material.

FIG. 12E illustrates the forming (e.g., deposition) of a second low thermal conductivity dielectric layer 203 over first low thermal conductivity dielectric layer 203 and at least one electrically conductive structure 202 of first backside metal layer BM0. In some embodiments, second low thermal conductivity dielectric layer 203 may include, but is not limited to, SiOₓ (e.g., SiO₂), carbon-doped SiO₂, silicon oxynitride, BSG, PSG, BPSG, FSG, USG, a porous dielectric material, or the like. Further, second low thermal conductivity dielectric layer 203 may include the same or different dielectric material as first low thermal conductivity dielectric layer 203 of BM0. Also, in some embodiments, an ESL may be formed over first backside metal layer BM0 prior to the forming of second low thermal conductivity dielectric layer 203.

FIG. 12F illustrates the forming (e.g., etching) of a plurality of trenches 1204 in second low thermal conductivity layer 203. While FIG. 12F depicts trenches 1204 as extending to an upper surface of first backside metal layer BM0, trenches 1204 may extend partway to the upper surface of first backside metal layer BMO in some embodiments.

FIG. 12G illustrates the deposition (e.g., seeding) of crystals 1206 of a high thermal conductivity electrically insulating material (e.g., diamond). In some embodiments, crystals 1206 form a thin layer (e.g., one to two crystals deep) over a remaining upper surface of second low thermal conductivity layer 203 and surfaces of trenches 1204. In some embodiments, the seeding may be accomplished by way of ultrasonic deposition, spin coating, ultrasonication-assisted polymerization, or another process for depositing crystals 1206 substantially uniformly (e.g., as a thin layer) over the upper surface of second low thermal conductivity layer 203 and surfaces of trenches 1204.

FIG. 12H illustrates the deposition (e.g., growing of grains) of high thermal conductivity electrically insulating material 1208 on the crystals 1206 (e.g., in and between trenches 1204). In some embodiments, this deposition may be performed using microwave-induced plasma chemical vapor deposition (CVD) (e.g. using methane (CH₃), hydrogen (H₂), oxygen (O₂), and/or another gas) or another process for dielectric or insulating material formation.

In some embodiments, the seeding of crystals associated with FIG. 12G and the growing of grains corresponding to FIG. 12H may represent a two-step deposition process for a high thermal conductivity electrically insulating material 1208 that conforms to a thermal budget allocated for a fabrication process for BSM 110 of IC device 100 (e.g., a back-end-of-line (BEOL) process).

FIG. 12I illustrates the removal (e.g., by planarization) of excess high thermal conductivity electrically insulating material 1208 between trenches 1204 to form a plurality of high thermal conductivity electrically insulating structures 201. In some embodiments, this removal results in completion of a second backside metal layer BM1 including the plurality of high thermal conductivity electrically insulating structures 201. In some embodiments, this removal may be performed using chemical-mechanical planarization (CMP) or another method of material removal to complete an upper surface 1210 of second backside metal layer BM1.

Further, in some embodiments, in conjunction with the forming of high thermal conductivity electrically insulating structures 201, a plurality of electrically conductive structures 202 (e.g., as shown in FIGS. 10A and 10B) are formed such that they are connected to high thermal conductivity electrically insulating structures 201. For example, in some embodiments, after the removal of material depicted in FIG. 12I, trenches (not shown in FIG. 121) may be formed in an upper surface of second backside metal layer BM1 that are perpendicular to those formed by the plurality of high thermal conductivity electrically insulating structures 201. Thereafter, such trenches may be filled with an electrically conductive material (e.g., copper or another metal or metal alloy) to form the plurality of electrically conductive structures 202.

FIG. 12J illustrates the forming (e.g., deposition) of a third low thermal conductivity dielectric layer 203 over second backside metal layer BM1. In some embodiments, third low thermal conductivity dielectric layer 203 may include one or more dielectric materials (e.g., SiOₓ (e.g., SiO₂), carbon-doped SiO₂, silicon oxynitride, BSG, PSG, BPSG, FSG, USG, a porous dielectric material, or the like) that are the same or different from those of first and second low thermal conductivity dielectric layers 203 described above.

FIG. 12K illustrates the forming (e.g., etching) of a plurality of trenches 1212 at an upper surface of third low thermal conductivity layer 203. In some embodiments, trenches 1212 may extend partway (e.g., approximately halfway) into third low thermal conductivity layer 203.

FIG. 12L illustrates the forming (e.g., deposition) of at least one conductive structure 202 to substantially complete a third backside metal layer BM2 and form a TCN 101. In some embodiments, at least one electrically conductive structure 202 may serve to provide power and/or signal connections between electrically conductive structures 202 of second backside metal layer BM1 and conductors associated with a package of the IC device (e.g., solder bumps 123 of IC device 100 of FIG. 1). In some embodiments, the forming of at least one electrically conductive structure 202 may be followed by a planarizing operation, such as CMP. In some embodiments, electrically conductive structure 202 may include a metal (e.g., copper (Cu)), a metal alloy, or another conductive material. The cross-sectional view of FIG. 12L of the resulting TCN 101, in some embodiments, may corresponding with the associated cross-section similarly marked in FIG. 10A.

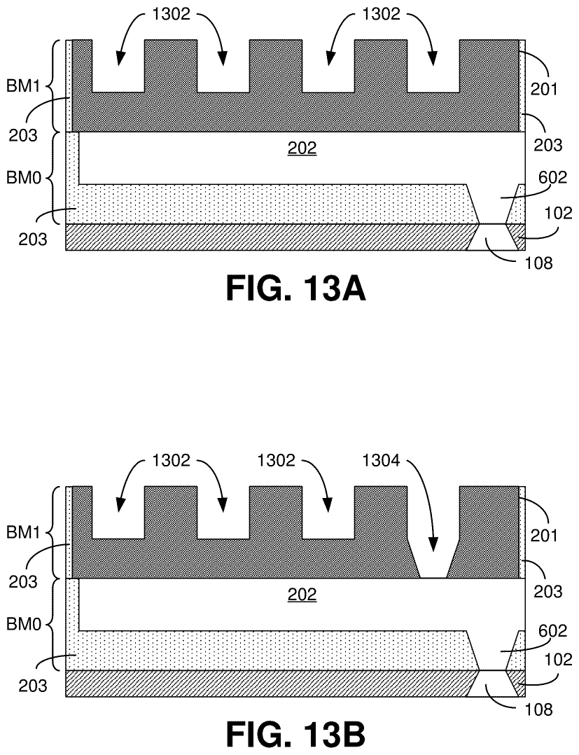

FIGS. 13A and 13B illustrate cross-sectional views of some embodiments employing two-step etching of a thermally conductive electrically insulating structure preceding deposition of a plurality of electrically conductive structures, according to the present disclosure. In some embodiments, FIGS. 13A and 13B depict fabrication steps associated with the cross-sectional views of FIGS. 10B and 11B discussed above. More specifically, FIG. 13A illustrates the removal (e.g., etching) of a trench 1302 for each electrically conductive structure to be formed in a high thermal conductivity electrically insulating structure 201 in a second backside metal layer BM1. In some embodiments, each trench 1302 may extend from an upper surface of high thermal conductivity electrically insulating structure 201 partway (e.g., halfway) toward an upper surface of underlying first backside metal layer BM0 (e.g., at an upper surface of an electrically conductive structure 202 therein). This first trenching step is followed by a second trenching step, as depicted in FIG. 13B, in which additional trenches 1304 are provided in those previous trenches 1302 in which a via is to be employed to connect the corresponding electrically conductive structure to electrically conductive structure 202 of first backside metal layer BM0.

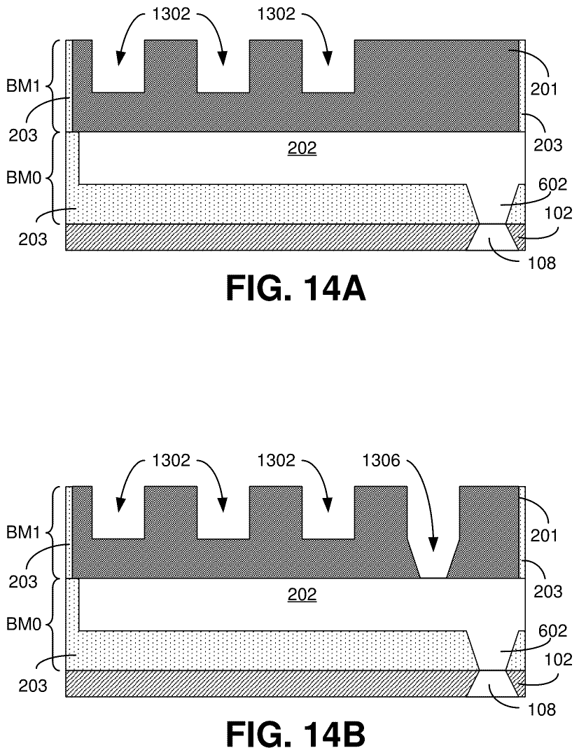

FIGS. 14A and 14B illustrate cross-sectional views of some embodiments employing one-step etching of a thermally conductive electrically insulating structure preceding deposition of a plurality of electrically conductive structures, according to the present disclosure. As was the case with FIGS. 13A and 13B, FIGS. 14A and 14B may also depict fabrication steps associated with the cross-sectional views of FIGS. 10B and 11B discussed above in some embodiments. More specifically, FIG. 14A illustrates the removal (e.g., etching) of a plurality of trenches 1302 in a high thermal conductivity electrically insulating structure 201 in a second backside metal layer BM1. In some embodiments, a trench 1302 is formed for each electrically conductive structure that is not to be coupled with an underlying via for connection to a conductive structure 202 of a first backside metal layer BM0. As was the case in embodiments of FIGS. 13A and 13B, in some embodiments, each trench 1302 of FIG. 14A may extend from an upper surface of high thermal conductivity electrically insulating structure 201 partway (e.g., halfway) toward an upper surface of underlying first backside metal layer BM0. Thereafter, as illustrated in FIG. 14B, a separate trench 1306 is etched for each electrically conductive structure and associated via of second backside metal layer BM1 that is to connect to electrically conductive structure 202 of first backside metal layer BM0. Consequently, unlike the embodiments of FIGS. 13A and 13B, each resulting trench associated with an electrically conductive structure in second backside metal layer BM1 will be formed using a single etching step.

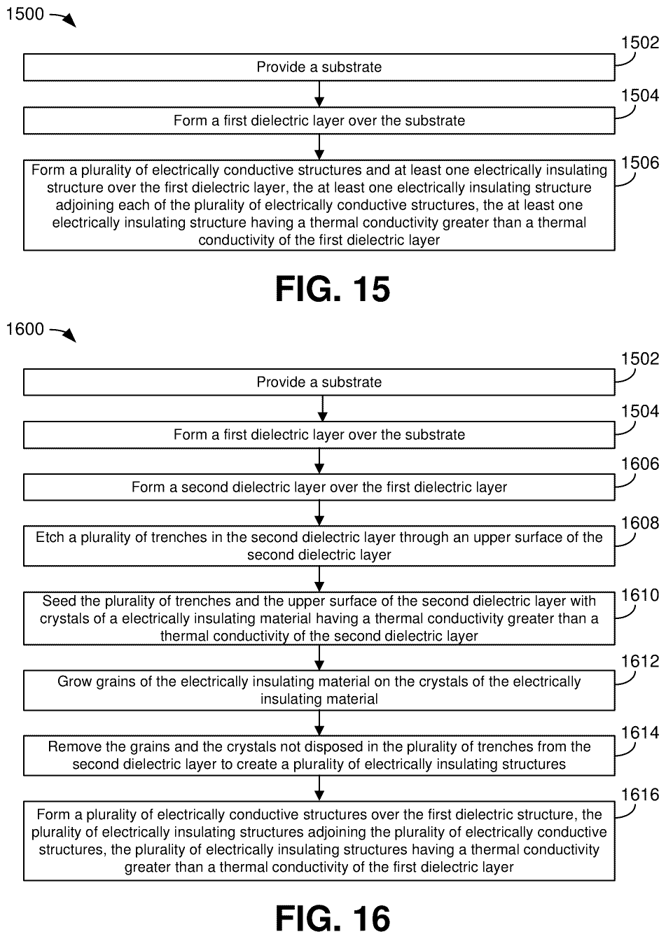

FIG. 15 illustrates a methodology 1500 of forming an IC device employing at least one highly thermally conductive electrically insulating structure to be coupled with a plurality of electrically conductive structures, in accordance with some embodiments of the present disclosure. Although this method and other methods illustrated and/or described herein are illustrated as a series of acts or events, it will be appreciated that the present disclosure is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At Act 1502, a substrate (e.g., device substrate 102 of FIG. 12A) is provided. In some embodiments, the device substrate may be a semiconductor substrate, such as a silicon substrate. FIG. 12A illustrates a cross-sectional view of some embodiments corresponding to Act 1502.

At Act 1504, a first dielectric layer (e.g., first dielectric layer 203 of FIG. 12B) is formed over the substrate. FIG. 12B illustrates a cross-sectional view of some embodiments corresponding to Act 1504.

At Act 1506, a plurality of electrically conductive structures (e.g., electrically conductive structures 202 of second backside metal layer BM1) and at least one electrically insulating structure (e.g., high thermal conductivity electrically insulating structures 201 of FIG. 121) are formed over the first dielectric layer. The at least one electrically insulating structure adjoins each of the plurality of electrically conductive structures. The at least one electrically insulating structure has a thermal conductivity greater than a thermal conductivity of the first dielectric layer. FIGS. 12E through 12I, in conjunction with FIGS. 10B and 10C, illustrate cross-sectional views of some embodiments corresponding to Act 1506.

FIG. 16 illustrates a methodology 1600 of forming an IC device employing a plurality of highly thermally conductive electrically insulating structures to be coupled with a plurality of electrically conductive structures, in accordance with some embodiments of the present disclosure.

In some embodiments, Act 1502 (providing a substrate, such as device substrate 102 of FIG. 12A) and Act 1504 (forming a first dielectric layer (e.g., first dielectric layer 203 of FIG. 12B) over the substrate) may be the same in FIG. 16 as the corresponding acts of FIG. 15.

At Act 1606, a second dielectric layer (e.g., second dielectric layer 203 over first backside metal layer BMO of FIG. 12E) is formed over the first dielectric layer. FIG. 12E illustrates a cross-sectional view of some embodiments corresponding to Act 1606.

At Act 1608, a plurality of trenches (e.g., trenches 1204 of FIG. 12F) are etched in the second dielectric layer through an upper surface of the second dielectric layer. FIG. 12F illustrates a cross-sectional view of some embodiments corresponding to Act 1608.

At Act 1610, the plurality of trenches and the upper surface of the second dielectric layer are seeded with crystals (e.g., crystals 1206 of FIG. 12G) of an electrically insulating material having a thermal conductivity greater than a thermal conductivity of the second dielectric layer. FIG. 12G illustrates a cross-sectional view of some embodiments corresponding to Act 1610.

At Act 1612, grains of the electrically insulating material (e.g., high thermal conductivity electrically insulating material 1208 of FIG. 12H) are grown on the crystals of the dielectric material. FIG. 12H illustrates a cross-sectional view of some embodiments corresponding to Act 1612.

At Act 1614, the grains and crystals that are not disposed in the plurality of trenches are removed from an upper surface of the second dielectric layer to create a plurality of electrically insulating structures (e.g., high thermal conductivity electrically insulating structures 201 of FIG. 121). FIG. 12I illustrates a cross-sectional view of some embodiments corresponding to Act 1614.

At Act 1616, a plurality of electrically conductive structures (e.g., electrically conductive structures 202 in second backside metal layer BM1 of FIGS. 10A and 10B) are formed over the first dielectric structure. In some embodiments, the plurality of electrically insulating structures adjoins the plurality of electrically conductive structures. Also, in some embodiments, the plurality of electrically insulating structures has a thermal conductivity greater than a thermal conductivity of the first dielectric layer. FIG. 121, in conjunction with FIGS. 10B and 10C, illustrates a cross-sectional view of some embodiments corresponding to Act 1616.

Some embodiments relate to an IC device. The IC device includes a substrate, a plurality of electrically conductive structures disposed over the substrate and separated from each other, and at least one electrically insulating structure disposed over the substrate and directly contacting each of the plurality of electrically conductive structures. The at least one electrically insulating structure has a thermal conductivity greater than five watts per meter-Kelvin (W/m-K).

Some embodiments relate to another IC device. The IC device includes a substrate, a first dielectric layer disposed over the substrate, a plurality of electrically conductive structures disposed over the first dielectric substrate and separated from each other, and at least one electrically insulating structure disposed over the first dielectric layer and adjoining each of the plurality of electrically conductive structures. The at least one electrically insulating structure has a thermal conductivity greater than a thermal conductivity of the first dielectric layer.

Some embodiments relate to a method. The method includes providing a substrate, forming a first dielectric layer over the substrate, and forming a plurality of electrically conductive structures and at least one electrically insulating structure over the first dielectric layer. The at least one electrically insulating structure adjoins each of the plurality of electrically conductive structures. The at least one electrically insulating structure has a thermal conductivity greater than a thermal conductivity of the first dielectric layer.

It will be appreciated that in this written description, as well as in the claims below, the terms “first”, “second”, “third” etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first dielectric layer” described in connection with a first figure may not necessarily correspond to a “first dielectric layer” described in connection with another figure, and may not necessarily correspond to a “first dielectric layer” in an un-illustrated embodiment.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) device, comprising:
a substrate including a through-silicon via (TSV);
a dielectric structure disposed over the substrate;
a plurality of electrically conductive structures in the dielectric structure, the plurality of electrically conductive structures laterally extending along a first direction;
a conductive via in the dielectric structure, the conductive via electrically coupling one of the plurality of electrically conductive structures to the TSV; and
at least one electrically insulating structure in the dielectric structure and adjoining the plurality of electrically conductive structures, the at least one electrically insulating structure laterally extending along a second direction perpendicular to the first direction, the at least one electrically insulating structure having a thermal conductivity greater than a thermal conductivity of the dielectric structure.

2. The IC device of claim 1, wherein the thermal conductivity of the at least one electrically insulating structure is greater than five watts per meter-Kelvin (W/m-K).

3. The IC device of claim 1, wherein the at least one electrically insulating structure comprises at least one of diamond, aluminum nitride (AlN), silicon carbide (SiC), silicon nitride (SiN), boron nitride (BN), or beryllium oxide (BeO).

4. The IC device of claim 1, wherein the at least one electrically insulating structure contacts an upper side of each of the plurality of electrically conductive structures.

5. The IC device of claim 1, wherein the at least one electrically insulating structure contacts a lower side of each of the plurality of electrically conductive structures.

6. The IC device of claim 1, wherein the at least one electrically insulating structure contacts at least one lateral side of each of the plurality of electrically conductive structures.

7. The IC device of claim 1, wherein the at least one electrically insulating structure is a single contiguous electrically insulating layer.

8. The IC device of claim 1, wherein the at least one electrically insulating structure comprises a plurality of electrically insulating structures, each of the plurality of electrically insulating structures having a longitudinal dimension extending along the second direction.

9. The IC device of claim 1, wherein the at least one electrically insulating structure comprises a plurality of electrically insulating structures, each of the plurality of electrically insulating structures having a longitudinal dimension extending along the first direction and filling at least a majority of a space between adjacent ones of the plurality of electrically conductive structures.

10. The IC device of claim 1, further comprising:
another conductive via in the dielectric structure, the other conductive via electrically coupling another one of the plurality of electrically conductive structures to a solder bump over an upper side of the dielectric structure, wherein the dielectric structure comprises a backside metal (BSM) layer of the IC device.

11. The IC device of claim 10, wherein the solder bump couples the conductive via to a package substrate for the IC device.

12. A method, comprising:
forming a through-silicon via (TSV) in a substrate;
forming a first dielectric layer over the substrate;
forming a first electrically conductive structure in the first dielectric layer, the first electrically conductive structure being electrically coupled to the TSV;
forming a second dielectric layer over the first dielectric layer and the first electrically conductive structure, the second dielectric layer including at least one electrically insulating structure having a thermal conductivity greater than a thermal conductivity of the first dielectric layer;
forming a plurality of trenches in the second dielectric layer, one of the plurality of trenches extending downward to the first electrically conductive structure, and others of the plurality of trenches extending downward to a partial depth relative to the one of the plurality of trenches; and
filling a conductive material in the plurality of trenches to form a plurality of electrically conductive structures, the at least one electrically insulating structure adjoining each of the plurality of electrically conductive structures.

13. The method of claim 12, wherein forming the plurality of trenches comprises:
etching the plurality of trenches to the partial depth; and
etching the one of the plurality of trenches again to the first electrically conductive structure.

14. The method of claim 12, wherein forming the plurality of trenches comprises:
etching the others of the plurality of trenches to the partial depth; and
etching the one of the plurality of trenches to the first electrically conductive structure.

15. The method of claim 12, wherein the one of the plurality of electrically conductive structures comprises an upper portion having a same cross-section as the others of the plurality of electrically conductive structures.

16. The method of claim 12, wherein:
the plurality of electrically conductive structures laterally extend along a first direction; and
the first electrically conductive structure laterally extends beyond the plurality of electrically conductive structures in a second direction perpendicular to the first direction.

17. The method of claim 12, wherein one or more of the at least one electrically insulating structure vertically extends from an upper side of the second dielectric layer to a lower side of the second dielectric layer.

18. A method, comprising:
forming a first dielectric layer over a substrate;
forming a second dielectric layer over the first dielectric layer;
etching a plurality of trenches in the second dielectric layer through an upper surface of the second dielectric layer, the trenches extending laterally in a first direction;
seeding the plurality of trenches and the upper surface of the second dielectric layer with crystals of an electrically insulating material having a thermal conductivity greater than a thermal conductivity of the second dielectric layer;
growing grains of the electrically insulating material on the crystals of the electrically insulating material;
removing the grains and the crystals not disposed in the plurality of trenches from the second dielectric layer to create a plurality of electrically insulating structures over the first dielectric layer;
forming a third dielectric layer over the second dielectric layer; and
forming a plurality of electrically conductive structures laterally extending in a second direction perpendicular to the first direction, the plurality of electrically conductive structures adjoining the plurality of electrically insulating structures.

19. The method of claim 18, wherein the grains and the crystals not disposed in the plurality of trenches are removed using chemical-mechanical planarization.

20. The method of claim 18, wherein the electrically insulating material comprises diamond.
